(19) United States
(12) Patent Application Publication
(10) Pub. No.: US 2026/0239639 A1
(43) Pub. Date: Aug. 13, 2026

(54) Bipolar Junction Transistors Including Embedded Base Superlattice And Related Methods

(71) Applicant: ATOMERA INCORPORATED, LOS GATOS, CA (US)

(72) Inventors: RICHARD BURTON, PHOENIX, AZ (US); ROBERT J. MEARS, WELLESLY, MA (US); ILYA RUMYANTSEV, SAN FRANCISCO, CA (US); HENDRIK GEZIENUS ALBERT HUIZING, NEERKANT (NL)

(21) Appl. No.: 19/654,006

(22) Filed: Apr. 21, 2026

Related U.S. Application Data
(63) Continuation-in-part of application No. 18/442,178, filed on Feb. 15, 2024, now Pat. No. 12,635,155.
Application No. 18/442,178 is a continuation of application No. 17/873,411, filed on Jul. 26, 2022, now Pat. No. 11,935,940.
Application No. 17/873,411 is a division of application No. 16/913,487, filed on Jun. 26, 2020, now Pat. No. 11,437,486.
(60) Provisional application No. 62/960,851, filed on Jan. 14, 2020.

(51) Int. Cl. H10D 10/01; H10D 10/40; H10D 62/13; H10D 62/17; H10D 62/815

(52) U.S. Cl. CPC H10D 10/051; H10D 10/40; H10D 62/137; H10D 62/177; H10D 62/8162

(57) ABSTRACT

A bipolar junction transistor (BJT) may include a substrate defining a collector region therein, and a silicon-germanium (SiGe) base over the collector region. A superlattice may be embedded within the SiGe base, the superlattice having a plurality of stacked groups of layers, with each group of layers having a plurality of stacked base semiconductor monolayers defining a base semiconductor portion, and at least one carbon monolayer constrained within a crystal lattice of adjacent base semiconductor portions. The BJT may also include an emitter on the SiGe base. The embedded superlattice may suppress boron diffusion within the SiGe base during thermal processing. The BJT may further include additional superlattices between the collector region and the SiGe base, and/or between the SiGe base and the emitter.

### RELATED APPLICATIONS

This application is a continuation-in-part of U.S. patent application Ser. No. 18/442,178 filed Feb. 15, 2024 which is a continuation application of U.S. patent application Ser. No. 17/873,411 filed Jul. 26, 2022, which is a divisional application of U.S. patent application Ser. No. 16/913,487 filed Jun. 26, 2020, now U.S. Pat. No. 11,437,486 issued Sep. 6, 2022, and claims the benefit of U.S. provisional application Ser. No. 62/960,851 filed Jan. 14, 2020, which are hereby incorporated herein in their entireties by reference.

### TECHNICAL FIELD

The present disclosure generally relates to semiconductor devices and, more particularly, to bipolar junction transistors (BJTs) and related methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si-Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO2/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A bipolar junction transistor (BJT) may include a substrate defining a collector region therein, and a silicon-germanium (SiGe) base over the collector region. A superlattice may be embedded within the SiGe base, the superlattice having a plurality of stacked groups of layers, each group of layers having a plurality of stacked base semiconductor defining a base semiconductor portion, and at least one carbon monolayer constrained within a crystal lattice of adjacent base semiconductor portions. The BJT may also include an emitter on the SiGe base.

In an example embodiment, the BJT may further include boron within the base having a peak intensity constrained at the superlattice. The SiGe base may include a lower SiGe base portion below the superlattice and an upper SiGe base portion above the superlattice, and the lower SiGe base portion may include an intrinsic SiGe base portion while the upper SiGe base portion includes an extrinsic SiGe base portion. In another example, the SiGe base may include an intrinsic SiGe base. In still another example, the SiGe base may be substantially free of carbon outside of the superlattice.

The BJT may further include another superlattice between the collector region and the SiGe base, and/or another superlattice between the SiGe base and the emitter, each having a plurality of stacked groups of layers, each group of layers having a plurality of stacked base semiconductor monolayers defining a base semiconductor portion, and at least one non-semiconductor monolayer constrained within a crystal lattice of adjacent base semiconductor portions. The substrate may further define a sub-collector region below the collector region, and the BJT may further include another superlattice in the substrate between the sub-collector region and the collector region.

In accordance with another example, a BJT may include a substrate defining a collector region therein, a SiGe base over the collector region, and a superlattice embedded within the SiGe base. The superlattice may have a plurality of stacked groups of layers, each group of layers having a plurality of stacked base semiconductor monolayers defining a base semiconductor portion, and at least one non-semiconductor monolayer constrained within a crystal lattice of adjacent base semiconductor portions. The BJT may also include an emitter on the SiGe base.

A related method for making a BJT may include forming a collector region in a substrate, forming a SiGe base over the collector region with a superlattice embedded therein, the superlattice having a plurality of stacked groups of layers, each group of layers having a plurality of stacked base semiconductor monolayers defining a base semiconductor portion, and at least one carbon monolayer constrained within a crystal lattice of adjacent base semiconductor portions, and forming an emitter on the SiGe base.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4A is a graph of the calculated band structure from the gamma point (G) for both bulk silicon as in the prior art, and for the 4/1 Si/O superlattice as shown in FIGS. 1-2.

FIG. 4B is a graph of the calculated band structure from the Z point for both bulk silicon as in the prior art, and for the 4/1 Si/O superlattice as shown in FIGS. 1-2.

FIG. 4C is a graph of the calculated band structure from both the gamma and Z points for both bulk silicon as in the prior art, and for the 5/1/3/1 Si/O superlattice as shown in FIG. 3.

FIG. 5 is schematic cross-sectional diagram of a bipolar junction transistor (BJT) including superlattices as described with reference to FIGS. 1-4C separating the base/collector and emitter/base in accordance with an example embodiment.

FIG. 6 is a graph of a simulated doping profile for the BJT of FIG. 5 in accordance with an example configuration.

FIG. 7 is a graph of simulated dopant concentration vs. depth for the BJT of FIG. 5 in accordance with an example implementation.

FIG. 8 is a schematic block diagram of an alternative embodiment of the BJT of FIG. 5 in accordance with an example embodiment.

FIG. 9 is a schematic block diagram of another alternative embodiment of the BJT of FIG. 5 in accordance with an example embodiment.

FIG. 10 is a flow diagram illustrating a method for making semiconductor devices such as those shown in FIGS. 7-9.

FIGS. 11 and 12 are schematic block diagrams of other alternative embodiments of BJTs in accordance with example embodiments.

FIG. 13 is a schematic cross-sectional diagram of a BJT including an embedded superlattice within a SiGe base in accordance with an example embodiment.

FIG. 14 is an enlarged schematic cross-sectional diagram of a base region of the BJT of FIG. 13 illustrating the embedded superlattice therein in accordance with an example embodiment.

FIG. 15 is a graph of dopant and germanium concentration versus depth for the BJT of FIG. 13 in accordance with an example implementation.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime and multiple prime notation are used to indicate similar elements in different embodiments.

Generally speaking, the present disclosure relates to Bipolar Junction Transistors (BJTs) having an enhanced semiconductor superlattice therein to provide dopant blocking and performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. Applicant theorizes, without wishing to be bound thereto, that certain superlattices as described herein reduce the effective mass of charge carriers and that this thereby leads to higher charge carrier mobility. Effective mass is described with various definitions in the literature. Further details are set forth is U.S. Pat. No. 11,437,486 from the present Applicant, which is hereby incorporated herein in its entirety by reference.

Applicant's definition of the conductivity reciprocal effective mass tensor is such that a tensorial component of the conductivity of the material is greater for greater values of the corresponding component of the conductivity reciprocal effective mass tensor. Again Applicant theorizes without wishing to be bound thereto that the superlattices described herein set the values of the conductivity reciprocal effective mass tensor so as to enhance the conductive properties of the material, such as typically for a preferred direction of charge carrier transport. The inverse of the appropriate tensor element is referred to as the conductivity effective mass. In other words, to characterize semiconductor material structures, the conductivity effective mass for electrons/holes as described above and calculated in the direction of intended carrier transport is used to distinguish improved materials.

Applicant has identified improved materials or structures for use in semiconductor devices. More specifically, Applicant has identified materials or structures having energy band structures for which the appropriate conductivity effective masses for electrons and/or holes are substantially less than the corresponding values for silicon. In addition to the enhanced mobility characteristics of these structures, they may also be formed or used in such a manner that they provide piezoelectric, pyroelectric, and/or ferroelectric properties that are advantageous for use in a variety of different types of devices, as will be discussed further below.

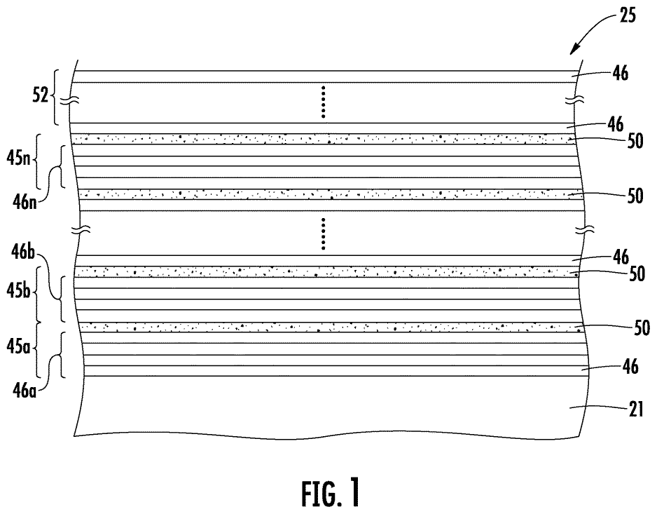

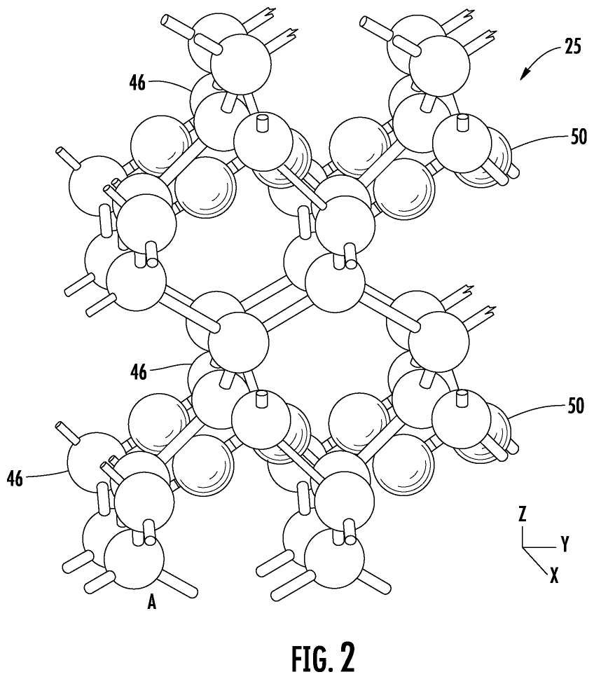

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and an energy band-modifying layer 50 thereon. The energy band-modifying layers 50 are indicated by stippling in FIG. 1 for clarity of illustration.

The energy band-modifying layer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Applicant theorizes without wishing to be bound thereto that energy band-modifying layers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice.

Moreover, this superlattice structure may also advantageously act as a barrier to dopant and/or material diffusion between layers vertically above and below the superlattice 25. These properties may thus advantageously allow the superlattice 25 to provide an interface for high-K dielectrics which not only reduces diffusion of the high-K material into the channel region, but which may also advantageously reduce unwanted scattering effects and improve device mobility, as will be appreciated by those skilled in the art.

It is also theorized that semiconductor devices including the superlattice 25 may enjoy a higher charge carrier mobility based upon the lower conductivity effective mass than would otherwise be present. In some embodiments, and as a result of the band engineering achieved by the present invention, the superlattice 25 may further have a substantially direct energy bandgap that may be particularly advantageous for opto-electronic devices, for example.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each energy band-modifying layer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art. More particularly, the base semiconductor may comprise at least one of silicon and germanium, for example

It should be noted that the term monolayer is meant to include a single atomic layer and also a single molecular layer. It is also noted that the energy band-modifying layer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

It is theorized without Applicant wishing to be bound thereto that for a superlattice, such as the Si/O superlattice, for example, that the number of silicon monolayers should desirably be seven or less so that the energy band of the superlattice is common or relatively uniform throughout to achieve the desired advantages. The 4/1 repeating structure shown in FIGS. 1 and 2, for Si/O has been modeled to indicate an enhanced mobility for electrons and holes in the X direction. For example, the calculated conductivity effective mass for electrons (isotropic for bulk silicon) is 0.26 and for the 4/1 SiO superlattice in the X direction it is 0.12 resulting in a ratio of 0.46. Similarly, the calculation for holes yields values of 0.36 for bulk silicon and 0.16 for the 4/1 Si/O superlattice resulting in a ratio of 0.44.

While such a directionally preferential feature may be desired in certain semiconductor devices, other devices may benefit from a more uniform increase in mobility in any direction parallel to the groups of layers. It may also be beneficial to have an increased mobility for both electrons and holes, or just one of these types of charge carriers as will be appreciated by those skilled in the art.

The lower conductivity effective mass for the 4/1 Si/O embodiment of the superlattice 25 may be less than two-thirds the conductivity effective mass than would otherwise occur, and this applies for both electrons and holes. Of course, the superlattice 25 may further comprise at least one type of conductivity dopant therein, as will also be appreciated by those skilled in the art.

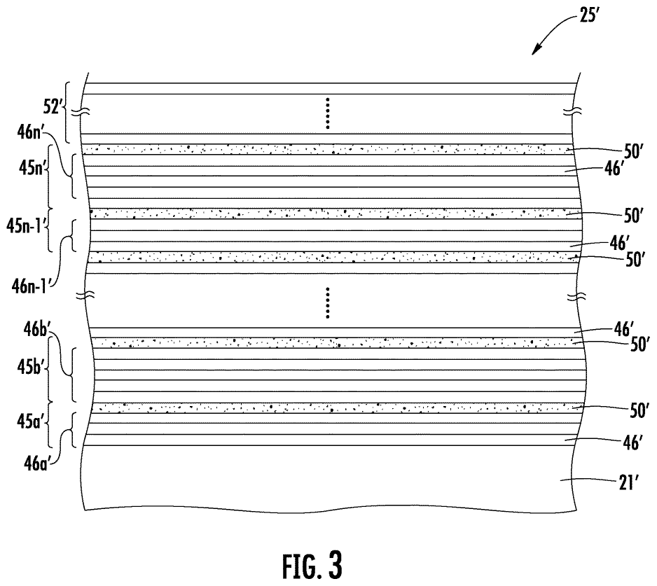

Indeed, referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The energy band-modifying layers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

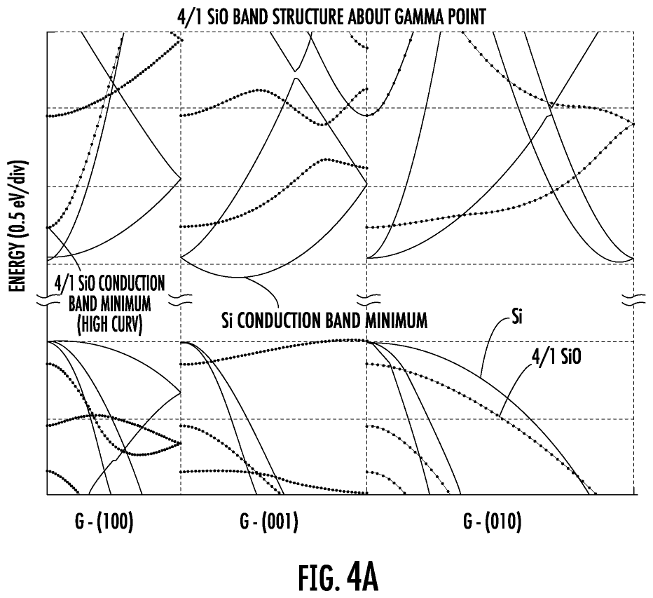

In FIGS. 4A-4C, band structures calculated using Density Functional Theory (DFT) are presented. It is well known in the art that DFT underestimates the absolute value of the bandgap. Hence all bands above the gap may be shifted by an appropriate “scissors correction.” However the shape of the band is known to be much more reliable. The vertical energy axes should be interpreted in this light.

FIG. 4A shows the calculated band structure from the gamma point (G) for both bulk silicon (represented by continuous lines) and for the 4/1 Si/O superlattice 25 shown in FIG. 1 (represented by dotted lines). The directions refer to the unit cell of the 4/1 Si/O structure and not to the conventional unit cell of Si, although the (001) direction in the figure does correspond to the (001) direction of the conventional unit cell of Si, and, hence, shows the expected location of the Si conduction band minimum. The (100) and (010) directions in the figure correspond to the (110) and (−110) directions of the conventional Si unit cell. Those skilled in the art will appreciate that the bands of Si on the figure are folded to represent them on the appropriate reciprocal lattice directions for the 4/1 Si/O structure.

It can be seen that the conduction band minimum for the 4/1 Si/O structure is located at the gamma point in contrast to bulk silicon (Si), whereas the valence band minimum occurs at the edge of the Brillouin zone in the (001) direction which we refer to as the Z point. One may also note the greater curvature of the conduction band minimum for the 4/1 Si/O structure compared to the curvature of the conduction band minimum for Si owing to the band splitting due to the perturbation introduced by the additional oxygen layer.

FIG. 4B shows the calculated band structure from the Z point for both bulk silicon (continuous lines) and for the 4/1 Si/O superlattice 25 (dotted lines). This figure illustrates the enhanced curvature of the valence band in the (100) direction.

FIG. 4C shows the calculated band structure from both the gamma and Z point for both bulk silicon (continuous lines) and for the 5/1/3/1 Si/O structure of the superlattice 25′ of FIG. 3 (dotted lines). Due to the symmetry of the 5/1/3/1 Si/O structure, the calculated band structures in the (100) and (010) directions are equivalent. Thus the conductivity effective mass and mobility are expected to be isotropic in the plane parallel to the layers, i.e. perpendicular to the (001) stacking direction. Note that in the 5/1/3/1 Si/O example the conduction band minimum and the valence band maximum are both at or close to the Z point.

Although increased curvature is an indication of reduced effective mass, the appropriate comparison and discrimination may be made via the conductivity reciprocal effective mass tensor calculation. This leads Applicant to further theorize that the 5/1/3/1 superlattice 25′ should be substantially direct bandgap. As will be understood by those skilled in the art, the appropriate matrix element for optical transition is another indicator of the distinction between direct and indirect bandgap behavior.

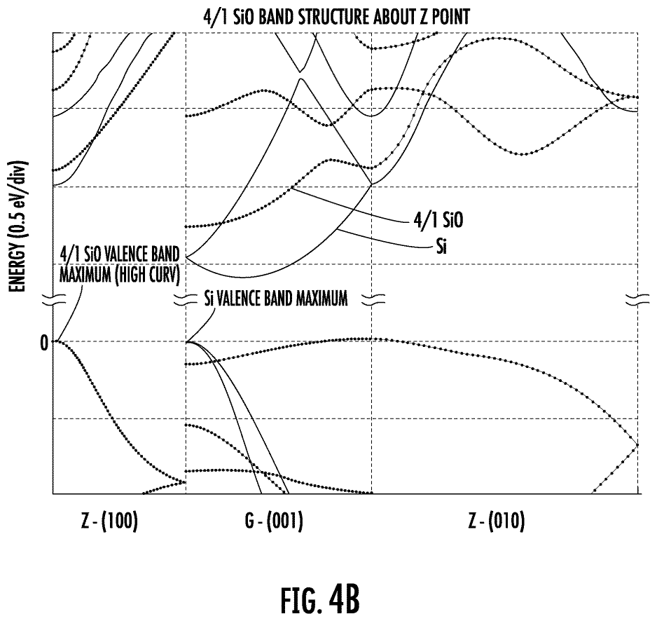

Referring now to FIG. 5, the above-described superlattice structures may advantageously be used to provide dopant diffusion barriers in Bipolar Junction Transistors (BJTs), such as silicon BJTs with polysilicon/crystalline silicon emitters and silicon/SiGe bases for NPN and PNP bipolar devices, for example. By way of background, typical BJTs utilize high doping in the emitter, which generally results in diffusion of the dopant into the base, and thus a degradation in performance. However, the above-described superlattice/MST material may be used to advantageously block dopants from a highly doped emitter region from diffusing into the base and/or emitter, and thereby degrading performance. Moreover, the MST material may also advantageously block interstitial injection during oxide growth during device fabrication.

In the present example, a BJT 120 illustratively includes a substrate 121 (e.g., a silicon substrate) including spaced apart shallow trench isolation (STI) regions 122 (e.g., SiO₂) therein. In the case of an NPN configuration, the substrate 121 may be doped with an N-type dopant (e.g., phosphorus, arsenic, etc.) to define a collector region 123 for the BJT 120. It should be noted that in some embodiments the collector dopant may be further distributed throughout the substrate 121 and not concentrated in a given location as shown in FIG. 5. A first superlattice 125a having a structure as described above is positioned between the substrate 121 and a base 130 overlying the first superlattice. The base 130 may comprise a semiconductor such as Si, Ge, or SiGe, and in an NPN configuration may be heavily P-doped with a dopant such as boron, for example. A second superlattice 125b, which again may have a structure as described further above, is positioned on the base 130.

An emitter 131 is positioned on the second superlattice 125b such that the second superlattice separates the emitter from the base 130. The emitter 130 may comprise a semiconductor (e.g., Si, Ge, or SiGe), and it is defined by adjacent spacers 132, 133 (e.g., nitride) and insulating regions 134 (e.g., oxide). The emitter 131 has an opposite conductivity type from the base 130, e.g., N+ in the example NPN configuration. An emitter contact 135 (e.g., silicide) overlies the emitter 130. Moreover, lower and upper extrinsic base regions 136, 137 are laterally outside of the emitter 130, and the lower extrinsic base region is positioned on the outer ends of the second superlattice 125b. The lower and upper extrinsic base regions 136, 137 may also comprise a semiconductor (e.g., Si, Ge, or SiGe) and have a similar doping profile to the base 130 (P+ in the present example). A base contact 138 (e.g., silicide) overlies the extrinsic base regions 136, 137, and contacts outer ends of the second superlattice 125b and base 130, as shown.

In typical BJT devices, the highly concentrated doping in the base results in diffusion of the base dopant into the collector, which degrades performance through widening of the base. However, in the BJT 120, the second superlattice 125b is advantageously positioned to block the dopants from the highly doped base 130 from diffusing into the collector 131, and thereby degrading performance from the widened base. Moreover, the first superlattice 125a is advantageously positioned to block interstitial injection during oxide growth that is performed during device fabrication, thereby also reducing dopant diffusion from the base 130 to the collector 123.

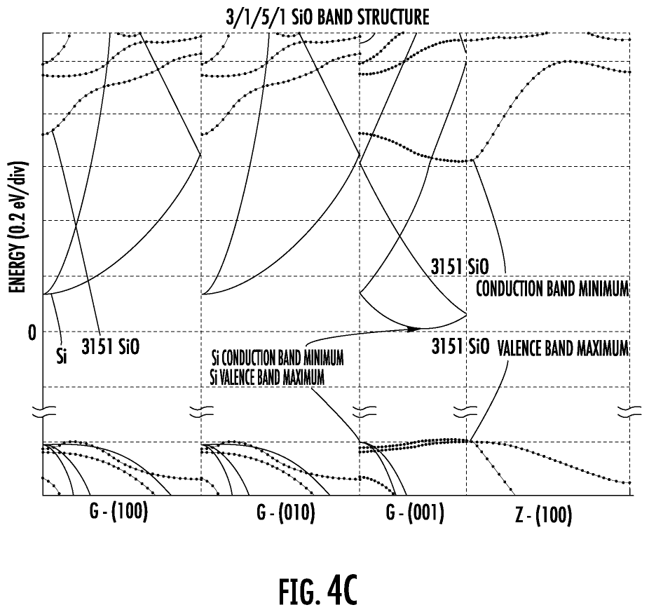

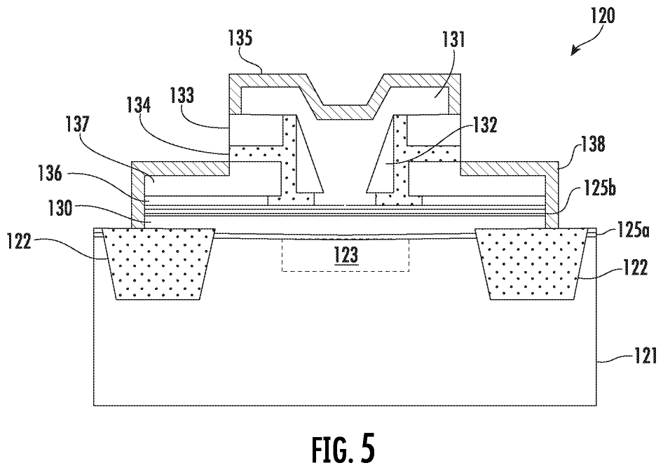

The foregoing dopant retention properties will be further understood with reference to the graphs 160 and 170 of FIGS. 6 and 7, respectively. The graph 160 illustrates a simulated doping profile for an example implementation of the BJT 120 in which the emitter 131 is N+ arsenic-doped polysilicon, the base 130 is P+ boron-doped SiGe, and the collector 123 is N phosphorous-doped silicon, although different semiconductor materials and dopant types/concentrations may be used in different embodiments. The graph 170 illustrates the corresponding simulated dopant concentrations (in cm⁻³) and Ge percentage across the emitter/base/collector layers for the same BJT device.

By way of contrast, the use of carbon doping in typical BJTs for dopant blocking results in a relatively high strain as compared to the MST material used for the first and second superlattices 125a, 125b, which advantageously provides improved dopant blocking through the incorporation of oxygen monolayers therein. Yet, the MST material still provides for epitaxial growth of the base notwithstanding the inclusion of the oxygen to provide dopant blocking, as discussed further above.

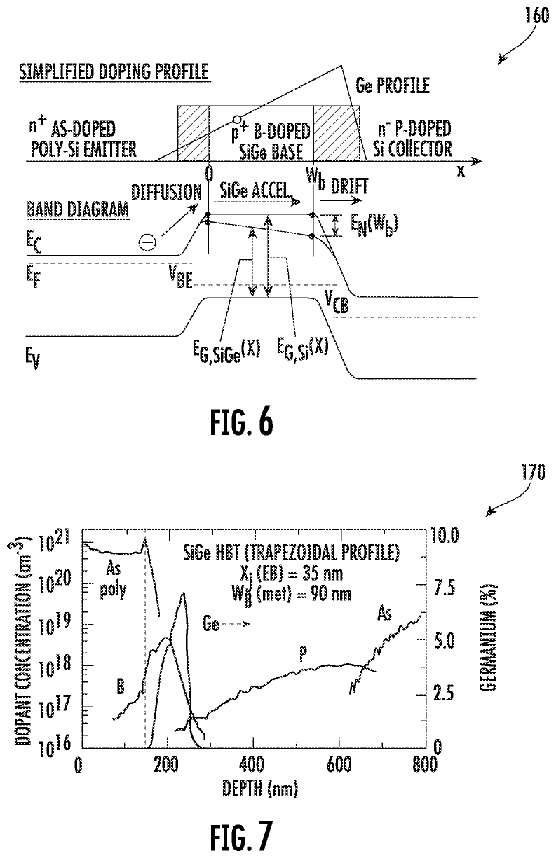

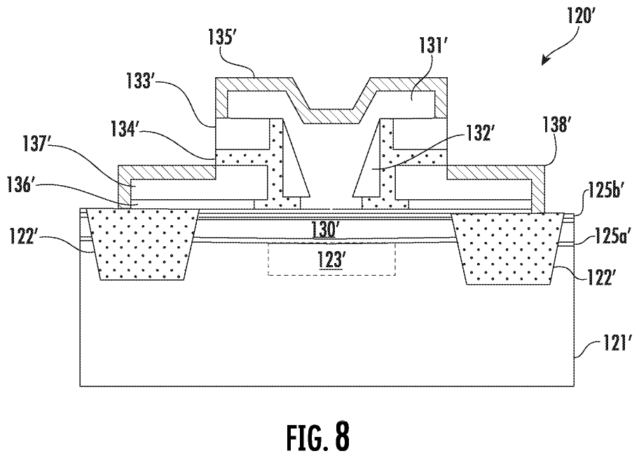

In accordance with other example embodiments of the BJT 120′, 120″ illustrated in FIGS. 8 and 9, respectively, the base 130′, 130″ is recessed below an upper surface of the STI regions 122′, 122″. Moreover, in the BJT 120″, the substrate 121″ further defines a sub-collector region 140″ below the collector region 123″, and a third superlattice 125c′″ is positioned between the sub-collector region and the collector region. More particularly, the third superlattice 125c′′ may also be an MST superlattice as described further above. The other portions/regions of the BJTs 120′, 120″ are similar to those described above and require no further discussion herein.

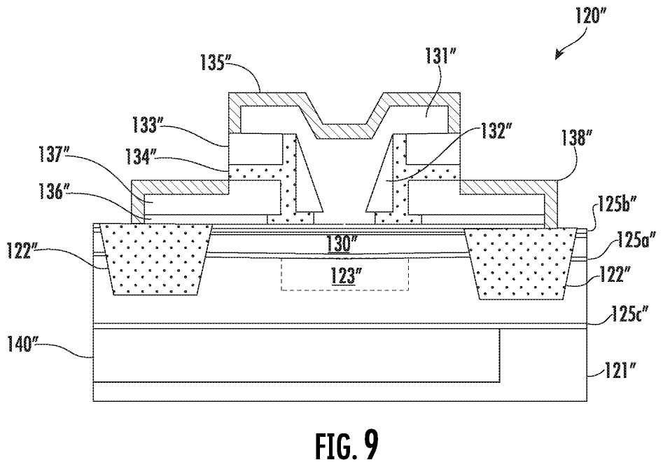

Turning now to the flow diagram 200 of FIG. 10, a method for making the BJT 120 is described. Beginning at block 201, the method illustratively includes forming the first superlattice 125a as described above on the substrate 121 defining a collector region 123 therein, at Block 202. More particularly, for the example BJT 120 the STI regions 122 are formed and the dopant is added for the collector 123 prior to formation of the superlattice 125a, which may be done by a blanket formation across the substrate 121 or selectively where desired on the substrate. Moreover, in the example BJT 120″, the sub-collector region 140″ and superlattice 125c″ would be formed prior to the STI regions 122″, doping of the collector 123″, and the first superlattice 125a″.

The method further illustratively includes forming the base 130 on the first superlattice 125a, at Block 203, and forming a second superlattice 125b on the base (Block 204), as also described above. For the BJTs 120′ and 120″, the base 130′, 130″ is recessed below the upper surface of the STI regions 122′, 122″ and may be formed in a cap layer of the superlattice 125a′ or 125a″, for example, as described above. The method further illustratively includes forming an emitter 131 on the second superlattice, at Block 205. Additional processing steps may also be performed to form the other portions/regions described further above, as will be appreciated by those skilled in the art. The method of FIG. 10 illustratively concludes at Block 206.

Further details regarding example BJT structures may be found in U.S. Pat. No. 10,068,997 to Preisler, which is hereby incorporated herein in its entirety by reference.

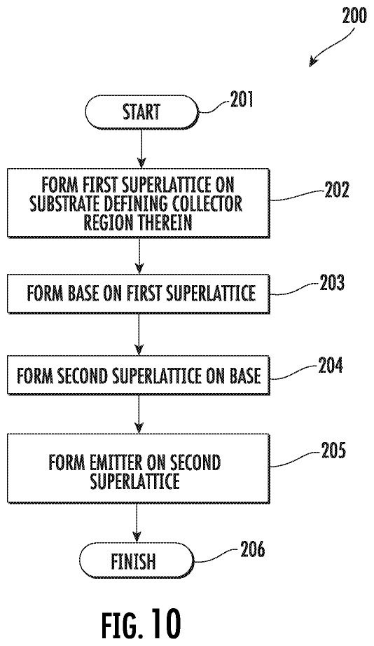

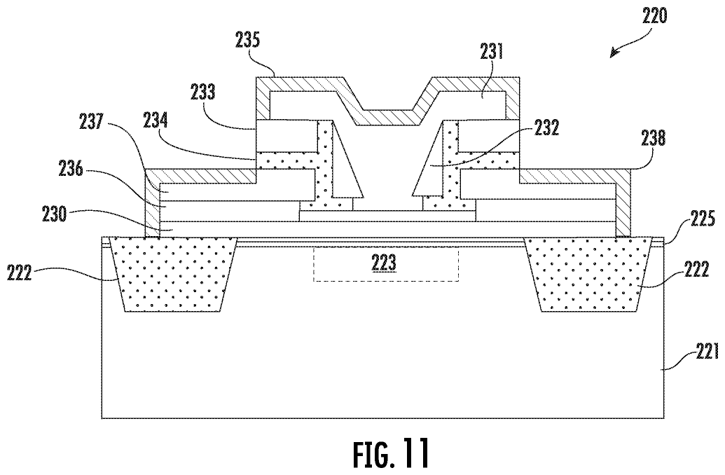

It should also be noted that in certain implementations both of the superlattices 125a/125a′/125a″ and 125b/125b′/125b″ need not be present. That is, such embodiments may include one or the other of the two superlattices 125a/125a′/125a″ and 125b/125b′/125b″. A first example BJT 220 is illustrated in FIG. 11 which includes an MST superlattice 225 between the collector 223 and base 230, but not between the base and the emitter 231. Another example BJT 320 is illustrated in FIG. 12 which includes an MST superlattice 325 between the base 230 and emitter 231, but not between the collector 223 and the base. The remaining components 221, 222, 231-238 and 321, 322, 331-338 shown in FIGS. 11 and 12 are respectively similar to components 121, 122, 131-138 discussed above. A single MST implementation may similarly be used with the configurations shown in FIGS. 8 and 9, if desired.

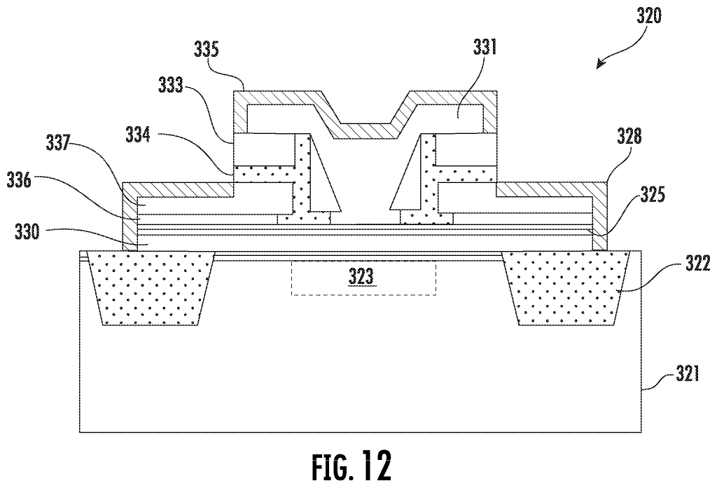

Referring now additionally to FIG. 13, another example embodiment of a BJT 420 is now described in which a superlattice is embedded within the base region itself, rather than (or in addition to) being positioned at the collector/base or base/emitter interfaces as described above with reference to FIGS. 5 and 8-12. More particularly, the BJT 420 illustratively includes a substrate 421 (e.g., a silicon substrate) including spaced apart STI regions 422 therein, and a collector region 423 defined in the substrate 421. A first superlattice 425a, which may be an MST superlattice as described further above, is positioned on the substrate 421 over the collector region 423. A SiGe base 430 is positioned on the first superlattice 425a, and a second superlattice 425b is positioned on the SiGe base 430.

In accordance with this example embodiment, an embedded superlattice 425c is positioned within the SiGe base 430 between the first and second superlattices 425a, 425b. More particularly, the embedded superlattice 425c is a carbon-based MST superlattice (also referred to herein as “MST-C”) having a plurality of stacked groups of layers, each group of layers having a plurality of stacked base silicon monolayers defining a base silicon portion, and at least one carbon monolayer constrained within a crystal lattice of adjacent base silicon portions. The embedded superlattice 425c may thus advantageously suppress dopant diffusion (e.g., boron diffusion) within the SiGe base 430 during thermal processing, so that the transistor retains a sharper electrically active boron profile and a better-controlled effective base width.

An emitter 431 is positioned on the second superlattice 425b such that the second superlattice 425b separates the emitter 431 from the SiGe base 430. The emitter 431 may include a semiconductor such as polysilicon, and is defined by adjacent spacers 432, 433 (e.g., nitride) and insulating regions 434 (e.g., oxide). An emitter contact 435 (e.g., silicide) overlies the emitter 431. Moreover, lower and upper extrinsic base regions 436, 437 are laterally outside of the emitter 431, and a base contact 438 (e.g., silicide) overlies the extrinsic base regions 436, 437. The remaining structural features of the BJT 420 are similar to those described above with reference to the BJT 120 of FIG. 5 and need no further discussion herein.

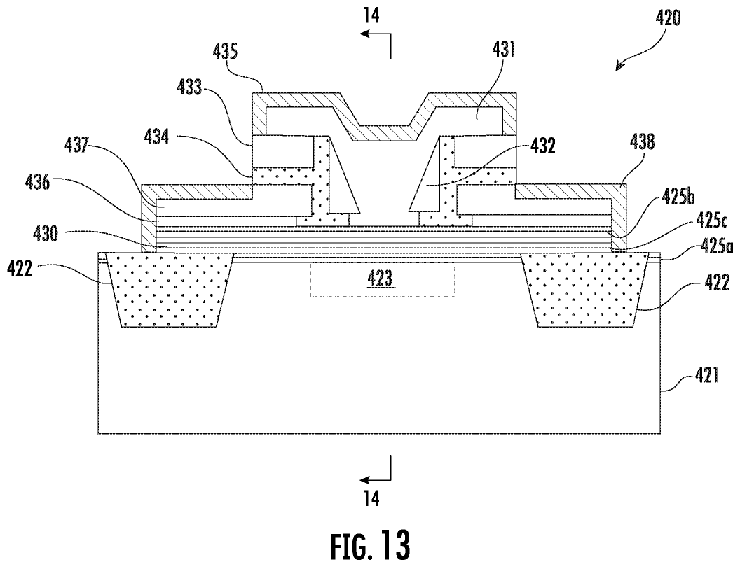

Referring additionally to FIG. 14, an enlarged schematic cross-sectional view of the base region of the BJT 420 is now described. From the collector region 423 upward, the first superlattice 425a is positioned at a first depth X within the device stack. Above the first superlattice 425a, the SiGe base 430 illustratively includes a lower SiGe base portion 444 and SiGeC base portion 445. The embedded MST-C superlattice 425c is positioned at a second depth Y within the SiGe base 430. Above the embedded superlattice 425c, additional SiGeC base portions 442, 443 extend between the embedded superlattice 425c and the second superlattice 425b, which is positioned at a third depth Z. Above the second superlattice 425b, the emitter 431 is defined in the superlattice silicon cap (Si Cap).

In this example embodiment, the SiGeC base portions 442, 443 may include carbon incorporated therein during epitaxial growth. In other example embodiments, the SiGe base 430 may be substantially free of carbon outside of the embedded superlattice 425c, such that the embedded MST-C superlattice 425c reduces or eliminates the need for conventional carbon doping in the SiGe base 430 while still maintaining boron confinement. It will be appreciated that the embedded superlattice 425c may be positioned at one or more selected depths within the SiGe base 430, including within an intrinsic SiGe base portion, between intrinsic and extrinsic base portions, or at another selected location within the base. Dielectric (insulating) regions 446 are on opposite sides of the SiGe base 430.

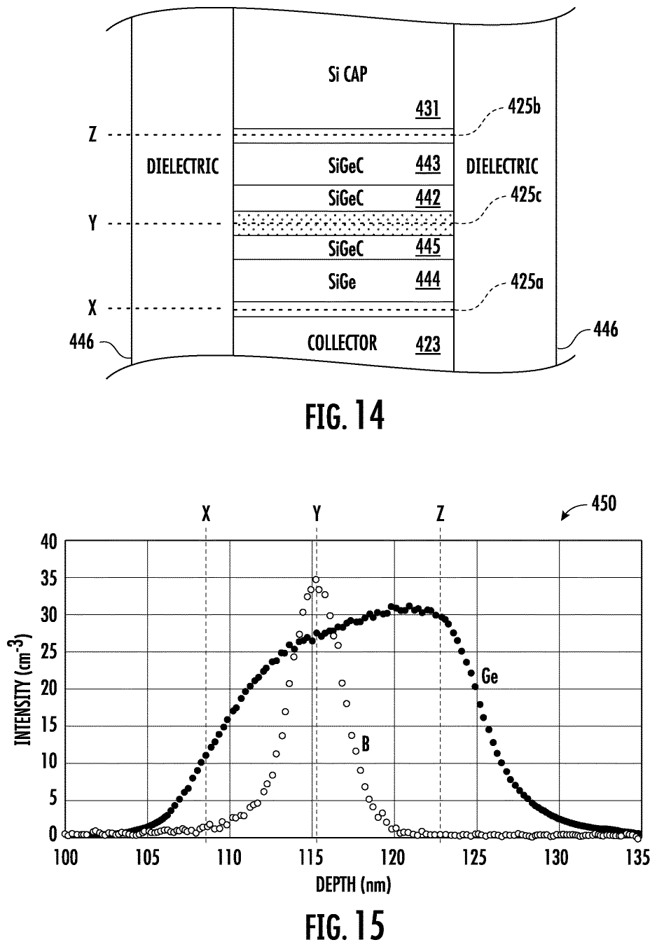

Referring now additionally to FIG. 15, a graph 450 illustrates dopant and germanium concentration (Intensity, in cm⁻³) versus depth (in nm) for an example implementation of the BJT 420. As shown, the boron peak intensity is advantageously constrained at the depth Y corresponding to the position of the embedded MST-C superlattice 425c within the SiGe base 430. This illustrates the dopant confinement function of the embedded superlattice 425c, which helps preserve or improve device gain, frequency response, and thermal robustness by limiting unwanted base profile smearing during thermal processing.

It should be noted that while the BJT 420 of FIG. 13 is illustrated with all three superlattices 425a, 425b, 425c, in other embodiments the embedded superlattice 425c may be used alone within the SiGe base 430 without the first superlattice 425a between the collector and the base and/or without the second superlattice 425b between the base and the emitter. Furthermore, the embedded superlattice 425c may also be used in combination with other BJT configurations described herein, such as the recessed-base configurations of FIGS. 8 and 9, and the single-MST configurations of FIGS. 11 and 12, as will be appreciated by those skilled in the art. Also, while the embedded superlattice 425c has been described as a carbon-based MST (MST-C), in other embodiments the embedded superlattice within the base may include other non-semiconductor monolayer materials, such as those noted above, constrained within a crystal lattice of adjacent base semiconductor portions. However, carbon may provide a technical advantage of reduced defects in the present application.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A bipolar junction transistor (BJT) comprising:
a substrate defining a collector region therein;
a silicon-germanium (SiGe) base over the collector region;
a superlattice embedded within the SiGe base, the superlattice comprising a plurality of stacked groups of layers, each group of layers comprising a plurality of stacked base semiconductor monolayers defining a base semiconductor portion, and at least one carbon monolayer constrained within a crystal lattice of adjacent base semiconductor portions; and
an emitter on the SiGe base.

2. The BJT of claim 1 further comprising boron within the SiGe base having a peak intensity constrained at the superlattice.

3. The BJT of claim 1 wherein the SiGe base comprises a lower SiGe base portion below the superlattice and an upper SiGe base portion above the superlattice; and wherein the lower SiGe base portion comprises an intrinsic SiGe base portion, and the upper SiGe base portion comprises an extrinsic SiGe base portion.

4. The BJT of claim 1 wherein the SiGe base comprises an intrinsic SiGe base.

5. The BJT of claim 1 wherein the SiGe base is substantially free of carbon outside of the superlattice.

6. The BJT of claim 1 wherein the emitter comprises polysilicon.

7. The BJT of claim 1 further comprising another superlattice between the collector region and the SiGe base, the other superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

8. The BJT of claim 1 further comprising a another superlattice between the SiGe base and the emitter, the other superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

9. The BJT of claim 1 wherein the substrate further defines a sub-collector region below the collector region; and further comprising another superlattice in the substrate between the sub-collector region and the collector region, the other superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

10. The BJT of claim 1 further comprising an emitter contact on an upper surface of the emitter, and a base contact on at least a portion of the SiGe base.

11. The BJT of claim 1 further comprising spaced apart isolation regions in the substrate.

12. The BJT of claim 1 wherein the emitter and the collector region have a first conductivity type, and the SiGe base has a second conductivity type different than the first conductivity type.

13. A bipolar junction transistor (BJT) comprising:
a substrate defining a collector region therein;
a silicon-germanium (SiGe) base over the collector region;
a superlattice embedded within the SiGe base, the superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions; and
an emitter on the SiGe base.

14. The BJT of claim 13 further comprising boron within the SiGe base having a peak intensity constrained at the superlattice.

15. The BJT of claim 13 wherein the SiGe base comprises a lower SiGe base portion below the superlattice and an upper SiGe base portion above the superlattice; and wherein the lower SiGe base portion comprises an intrinsic SiGe base portion, and the upper SiGe base portion comprises an extrinsic SiGe base portion.

16. The BJT of claim 13 wherein the SiGe base comprises an intrinsic SiGe base.

17. A method for making a bipolar junction transistor (BJT) comprising:
forming a collector region in a substrate;
forming a silicon-germanium (SiGe) base over the collector region with a superlattice embedded therein, the superlattice comprising a plurality of stacked groups of layers, each group of layers comprising a plurality of stacked base semiconductor monolayers defining a base semiconductor portion, and at least one carbon monolayer constrained within a crystal lattice of adjacent base semiconductor portions; and
forming an emitter on the SiGe base.

18. The method of claim 17 further comprising incorporating boron within the SiGe base having a peak intensity constrained at the superlattice.

19. The method of claim 17 wherein forming the SiGe base comprises forming a lower SiGe base portion below the superlattice and an upper SiGe base portion above the superlattice; and wherein the lower SiGe base portion comprises an intrinsic SiGe base portion, and the upper SiGe base portion comprises an extrinsic SiGe base portion.

20. The method of claim 17 wherein the SiGe base comprises an intrinsic SiGe base.

21. The method of claim 17 wherein the SiGe base is substantially free of carbon outside of the superlattice.

22. The method of claim 17 wherein the emitter comprises polysilicon.

23. The method of claim 17 further comprising forming another superlattice between the collector region and the SiGe base, the other superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

24. The method of claim 17 further comprising forming another superlattice between the SiGe base and the emitter, the other superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.

25. The method of claim 17 wherein the substrate further defines a sub-collector region below the collector region; and further comprising forming another superlattice in the substrate between the sub-collector region and the collector region, the other superlattice comprising a plurality of stacked groups of layers, each group of layers comprising a plurality of stacked base semiconductor monolayers defining a base semiconductor portion, and at least one non-semiconductor monolayer constrained within a crystal lattice of adjacent base semiconductor portions.
